(19) United States
(12) Patent Application Publication
(10) Pub. No.: US 2006/0185793 A1
(43) Pub. Date: Aug. 24, 2006

(54) Substrate processing system

(75) Inventors: Yoshihide Sakamoto, Nirasaki-shi (JP); Toshihiko Kikuchi, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/262,923

(22) Filed: Nov. 1, 2005

Related U.S. Application Data
(60) Provisional application No. 60/635,614, filed on Dec. 14, 2004.

(30) Foreign Application Priority Data
Jan. 11, 2004 (JP) 2004-318100

(51) Int. Cl. H01L 21/306

(52) U.S. Cl. 156/345.24; 156/345.32

(57) ABSTRACT

In a substrate processing system having a gas processing apparatus, a measuring apparatus and a transfer apparatus, the measuring apparatus for performing a measurement on a substrate includes a mounting unit, an optical measuring unit and a measuring space. A substrate transfer port for transferring the substrate to the mounting unit is opened in the measuring space; and, by a wall defining the measuring space, the measuring space and a space where the optical measuring unit is accommodated are airtightly isolated from each other. Further, in the measuring space, there is provided an air supply port for supplying a clean air towards the substrate transfer port when the substrate is loaded into the measuring space to be measured therein. Therefore, the processing gas introduced from the substrate transfer port into the measuring space is diluted or sent back, to thereby, suppress contamination in the measuring space.

### FIELD OF THE INVENTION

The present invention relates to a substrate processing system having a gas processing apparatus and a measuring apparatus.

### BACKGROUND OF THE INVENTION

During the manufacturing of, e.g., a semiconductor device, an etching process is commonly performed in an etching apparatus, which is mounted on a substrate processing system. In general, the substrate processing system includes a loading/unloading unit for loading or unloading a wafer, a transfer apparatus for transferring the wafer from the loading/unloading unit to the etching apparatus, and the like. After an unprocessed wafer is loaded into the loading/unloading unit, it is transferred to the etching apparatus by the transfer apparatus to be etched therein, and subsequently, is returned to the loading/unloading unit by the transfer apparatus.

Meanwhile, for a wafer that has been etched, a pattern dimension or a film thickness, an etching depth of the etched layer or the like maybe measured. Conventionally, such measurements have been conducted using a measuring apparatus located separately from the substrate processing system, the measuring apparatus being provided with an optical system. As a consequence, the etched wafer must be unloaded from the substrate processing system to be transferred to various measuring apparatuses, and these transfers would increase the total processing time. Therefore, recently, it has been proposed that the measuring apparatus be integrated into the substrate processing system with a view to improving the productivity by reducing the time for transferring the wafer W (e.g., see Reference 1).

However, during the aforementioned etching process performed in the substrate processing system, a corrosion inducing/corrosive gas, e.g., HCl, HBr or the like is employed as a processing gas. In case when the measuring apparatus is mounted in the substrate processing system, the corrosion inducing/corrosive gas from the etching apparatus may come into a contact with the measuring apparatus. Further, during the loading of an etched wafer into the measuring apparatus, the corrosion inducing/corrosive gas may inadvertently be introduced thereinto, causing the optical system therein to become corroded, detrimentally affecting the measurement accuracy thereof. Further, lifetime of the components constituting the optical system may become shortened. Still further, the aforementioned corrosion within the optical system may contaminate the measurement system, which will, in turn, contaminate the wafer being loaded thereinto for measurements, all of which will result in detrimentally affecting the overall yield. To resolve such problems, it has been proposed, for example, to replace the components constituting the optical system with more corrosion resistant components. This, however, is impractical, for the cost therefor would be too prohibitive.

*Reference 1: Japanese Paten Laid-open Application No. 2002-280279

### SUMMARY OF THE INVENTION

The present invention is contrived on the basis of the aforementioned problems, and it is, therefore, an object of the present invention to provide a substrate processing system, capable of preventing corrosion and contamination of an optical measuring unit in a measuring apparatus, due to a processing gas used in a gas processing apparatus such as an etching apparatus or the like.

In accordance with a preferred embodiment of the present invention, for achieving the aforementioned object, there is provided a substrate processing system, including: a gas processing apparatus for processing a substrate by using a processing gas; a measuring apparatus for performing a measurement on the substrate processed in the gas processing apparatus; and a transfer apparatus for transferring the substrate processed in the gas processing apparatus to the measuring apparatus, all the apparatus being integrated in the system as a single unit, wherein the measuring apparatus contains a mounting unit for mounting the substrate; an optical measuring unit for performing a measurement on the substrate mounted on the mounting unit by irradiating a light beam thereto; and a measuring space having therein the mounting unit, in which the measurement is conducted on the substrate mounted on the mounting unit, wherein, in the measuring space, there is opened a substrate transfer port for transferring the substrate to the mounting unit by the transfer apparatus, and wherein the measuring space and a space where the optical measuring unit is accommodated are airtightly isolated from each other by a wall defining the corresponding measuring space.

In accordance with the present invention, since the measuring space, in which the measurement on the substrate is performed in the measuring apparatus, and the optical measuring unit are airtightly isolated from each other by the wall of the measuring space, the processing gas supplied from the substrate transfer port into the measuring space does not get into a contact with the optical measuring unit. Therefore, the optical measuring unit may not become corroded even though the corrosion inducing/corrosive gas contained in the processing gas is introduced into the measuring apparatus, e.g., from the substrate transfer port, or it enters thereinto by the substrate. As a consequence, the measurement accuracy on the substrate in the optical measuring unit is maintained, so that the measurement on the substrate can be properly carried out. Further, since it does not occur that the optical measuring unit is corroded, which will, in turn, contaminate the measuring apparatus, the substrate loaded into the measuring apparatus may not be contaminated as well. As a result, it is possible to reduce an inferior substrate.

Here, an anti-corrosion processing against the processing gas may be performed on an exposed surface in the measuring space. In such a case, it is possible to prevent the measuring space from being corroded due to the processing gas, so that contaminations of the measuring space and the substrate, caused by such a corrosion, may be prevented.

Further, the measuring space may be formed to accommodate therein only the mounting unit. In this case, a volume of the measuring space is minimally suppressed, so that corrosion or contamination therein due to the processing gas can be minimally suppressed. Further, in case where an anti-corrosion processing is performed in such a measuring space, an area thereof may be minimally suppressed, and therefore, the cost for the anti-corrosion processing can be reduced. Here, the measuring space may be of a rectangular parallelepiped shape, one side of which corresponds to the substrate transfer port.

The measuring apparatus may further contain a housing; and a measuring block, provided in the housing, for forming the measuring space, and wherein the measuring block may have an outward appearance of a rectangular parallelepiped shape; and the measuring space may be formed in a sidewall surface of the measuring block in a recessed shape.

The optical measuring unit may be provided in a hollow portion of the measuring block between an inner wall surface defining the measuring space and an outer wall surface defining the outward appearance of the measuring block.

In the wall of the measuring space isolating the optical measuring unit, there may be formed a transmission window through which the light beam irradiated from the optical measuring unit is transmitted. Further, the transmission window may be provided with a transmission window protection shutter for protecting the transmission window from the processing gas. In such a case, the transparent window protection shutter is closed to isolate the transmission window from the measuring space, e.g., while the measurement by the optical measuring unit is not performed, so that corrosion or contamination of the transmission window due to the processing gas in the measuring space can be suppressed. As a consequence, the light beam from the optical measuring unit is properly transmitted through the transmission window, so that the measurement accuracy in the optical measuring unit is maintained.

At a position facing the substrate transfer port on a sidewall of the measuring space, there may be formed an air supply port for supplying a clean gas toward the substrate transfer port. In this case, since the clean gas is supplied from the sidewall of the measuring space toward the substrate transfer port. Therefore, by such a flow of the clean gas, the processing gas introduced from the substrate transfer port into the measuring space can be diluted or sent back. As a consequence, it is possible to further suppress corrosion or contamination in the measuring space due to the processing gas.

In the measuring space, there may be formed a gas exhaust port for exhausting the clean gas, which is supplied from the air supply port, in the vicinity of the substrate transfer port at a downstream side below the mounting unit. In such a case, the clean gas supplied from the air supply port can be exhausted through the measuring space, and therefore, e.g., the measuring space may be cleaned.

Here, the gas exhaust port may be formed at a bottom surface of the measuring space. In this case, it is possible to effectively exhaust the corrosion inducing/corrosive gas, which is relatively heavy compared to the air and remains at the bottom of the measuring space.

The substrate processing system may further include a shutter for opening or closing the substrate transfer port; and a control unit for performing an air supply from the air supply port and stopping an exhaust from the exhaust port while the shutter is opened, and performing the air supply from the air supply port and the exhaust from the gas exhaust port while the shutter is closed. In this case, if the shutter is opened, the air supply is carried out to suppress the introduction of the processing gas into the measuring space. Further, if the shutter is closed, the air supply and the exhaust are performed to clean the measuring space, and thus, maintaining the clean state.

The substrate processing system may further include an air inlet port for introducing an air of an outer side of the measuring apparatus; an air supply duct in communication with the air inlet port and the air supply port; and a filter for removing impurities from an air passing through the air supply duct.

Here, it can be configured such that a downflow is formed at an outside of the substrate transfer port, and a flow rate of air supplied from the air supply port is set to be smaller than that of the downflow. In such a case, according to the inspection by the present inventor, it does not occur that the air flow is scattered and dusts and the like fly upward at a part where the flow of the clean gas is joined with the down-flow in the measuring space. As a consequence, the substrate transferred to the substrate transfer port is not contaminated due to the dusts, which fly upward.

At the substrate transfer port, there may be provided a flow rectifying plate for rectifying an air flow at a point where a flow of the clean gas in the measuring space is joined with the downflow. In this case, also, since the dusts in the vicinity of the substrate transfer port can be prevented from flying upward, the substrate transferred to the substrate transfer port is not contaminated due to the dusts.

In the measuring space, there may be provided a reference member, to which the light beam from the optical measuring unit is irradiated, for correcting the measurement performed by the optical measuring unit, and the reference member may be provided with a protection shutter for protecting the reference member from the processing gas. In this case, since the protection shutter is closed to isolate the reference member from the measuring space while it is not used, it is possible to suppress corrosion or contamination of the reference member due to the processing gas.

### BRIEF DESCRIPTION OF THE DRAWINGS

The above and other objects and features of the present invention will become apparent from the following description of preferred embodiments given in conjunction with the accompanying drawings, in which:

FIG. 1 provides a plane view showing a schematic substrate processing system in accordance with a preferred embodiment;

FIG. 2 is an explanatory diagram of a longitudinal cross section showing a schematic configuration of a measuring apparatus;

FIG. 3 presents a perspective view showing a measuring block;

FIG. 4 sets forth an explanatory diagram of a longitudinal cross section showing an inner configuration of the measuring block of the measuring apparatus;

FIG. 5 illustrates an explanatory diagram showing a status in the measuring apparatus, when a measurement is not conducted;

FIG. 6 describes an explanatory diagram showing a status in the measuring apparatus, when the measurement is conducted;

FIG. 7 offers an explanatory diagram of a longitudinal cross section showing a reference chip and a mounting plate having thereon a protection shutter;

FIG. 8 is an explanatory diagram of a longitudinal cross section showing an inner configuration of the measuring block, in case where a transmission window protection shutter is attached to a transmission window; and

FIG. 9 is an explanatory diagram of a longitudinal cross section showing a configuration of the measuring apparatus, in case where a flow rectifying plate is attached to a transfer port.

### DETAILED DESCRIPTION OF THE PREFERRED EMBODIMENTS

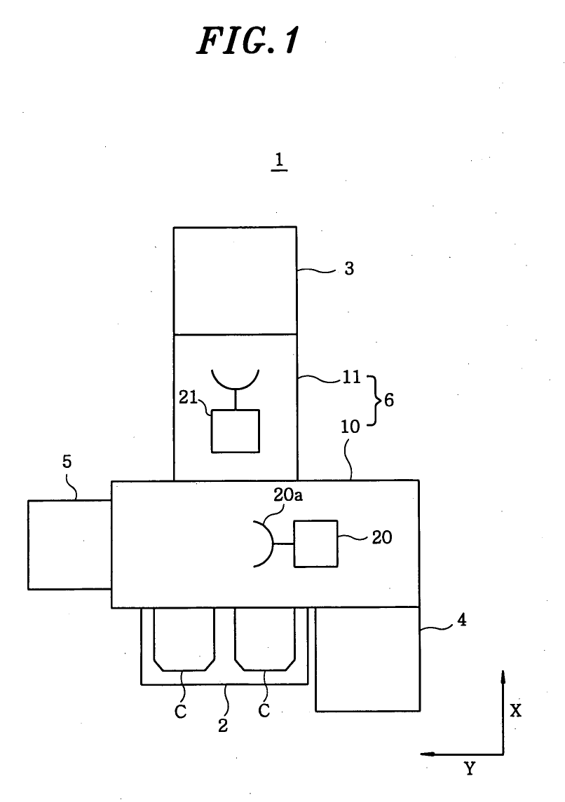

Hereinafter, preferred embodiments of the present invention will be described. FIG. 1 is a plane view showing a schematic configuration of a substrate processing system 1 in accordance with a preferred embodiment.

The substrate processing system 1 includes a cassette mounting unit 2 for mounting therein a plurality of cassettes C, each accommodating therein, e.g., a wafer W; an etching apparatus 3 as a gas processing apparatus for performing an etching process on the wafer W; a measuring apparatus 4 for measuring a film thickness of the etched layer on the wafer W; an alignment unit 5 for positioning the wafer W; and a transfer apparatus 6 for transferring the wafer W between the cassette mounting unit 2, the etching apparatus 3, the measuring apparatus 4 and the alignment unit 5, all being coupled to each other as a unit.

The transfer apparatus 6 includes a transfer chamber 10, to which, e.g., the cassette mounting unit 2, the measuring apparatus 4 and the alignment unit 5 are connected; and a load-lock chamber 11 for connecting the transfer chamber 10 to the etching apparatus 3. The cassette mounting unit 2 and the measuring apparatus 4 are located below the transfer chamber 10, i.e., at a negative direction of the X-direction (in the downward direction in FIG. 1). The alignment unit 5 is provided at the left side of the transfer chamber 10, i.e., at a positive direction of the Y-direction (in the left direction in FIG. 1). The load-lock chamber 11 is provided at a position facing, e.g., the cassette mounting unit 2 in the transfer chamber 10.

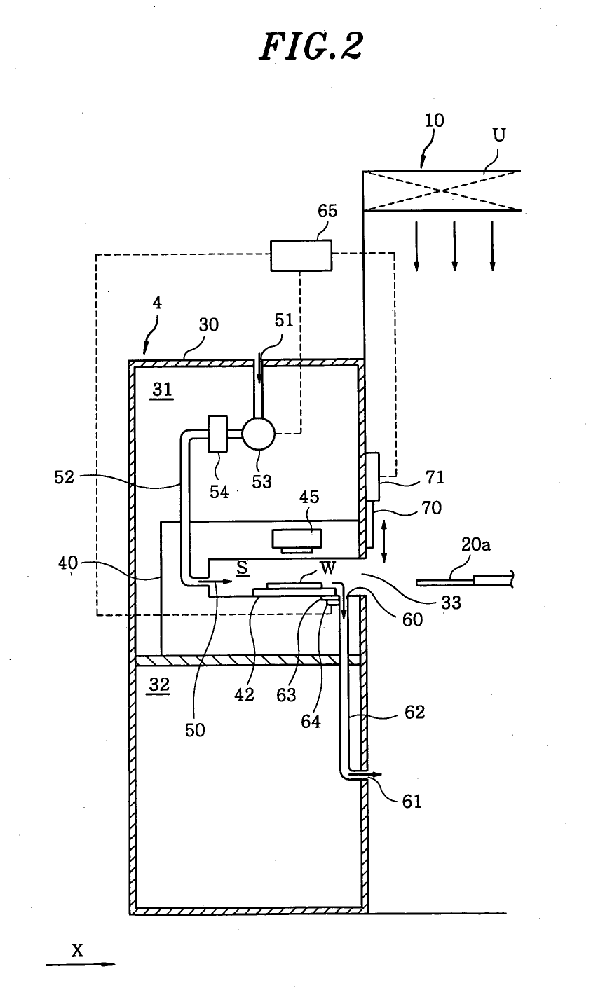

The transfer chamber 10 has therein a transfer mechanism 20 for transferring, e.g., the wafer W. The transfer mechanism 20 has a transfer arm 20a for supporting thereon, e.g., the wafer W; and the transfer arm 20a is moved back and forth to transfer the wafer W, e.g., to the cassette mounting unit 2, the measuring apparatus 3 or the load-lock chamber 11. For example, as illustrated in FIG. 2, above the transfer chamber 10, there is provided an air supply unit U for downwardly supplying a clean gas, temperature and humidity of which are adjusted at specified values, wherein, by the air supply unit U, a down-flow is formed in the transfer chamber 10 to maintain thereinside at a predetermined clean atmosphere. Further, as shown in FIG. 1, a transfer mechanism 21 for transferring the wafer W, e.g., between the load-lock chamber 11 and the etching apparatus 3 is provided in the load-lock chamber 11.

In the etching apparatus 3, a film on a wafer surface can be etched by introducing into the chamber a processing gas, e.g., HCl, HBr or the like, and at the same time, by forming a plasma by applying a high frequency power between a lower electrode having thereon the wafer and an upper electrode facing the lower electrode.

For example, as shown in FIG. 2, the measuring apparatus 4 has a housing 30, an outward appearance of which is a substantially rectangular parallelepiped shape, the housing 30 being adhered to the transfer chamber 10. An inside of the housing 30 is partitioned, e.g., into an upper measuring unit 31 and a lower control unit 32. At a portion where the measuring unit 31 is in a contact with the transfer chamber 10, there is formed a near quadrangular shaped transfer port 33 for transferring the wafer W. For example, the control unit 32 may contain a control system for controlling the measurement in the measuring unit 31.

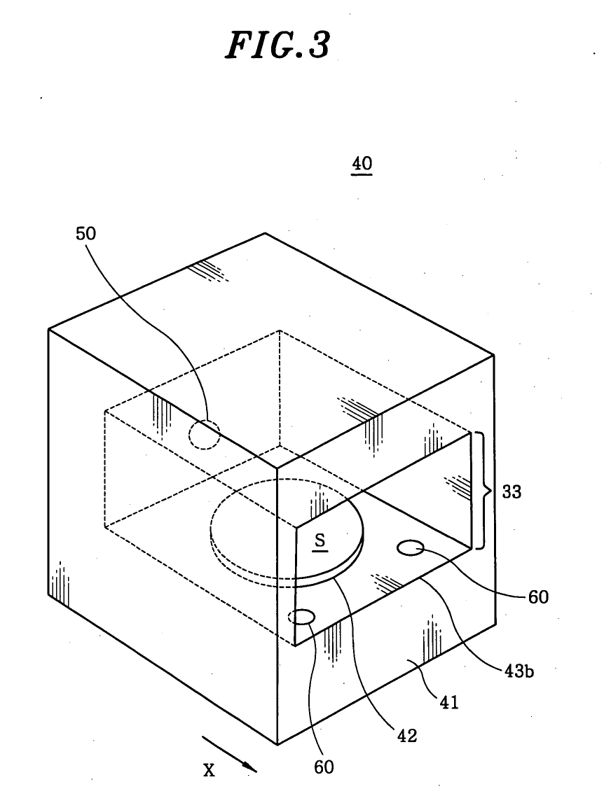

In the measuring unit 31, there is provided a measuring block 40 for forming a measuring space S of the wafer W. The measuring block 40 has an outward appearance of a near rectangular parallelepiped shape, as illustrated in FIG. 3. In an outer wall surface 41 of the measuring block 40 facing the transfer chamber 10, there is formed a recessed portion, functioning as a measuring space S. The measuring space S is of a near rectangular parallelepiped shape, one side of which corresponds to the transfer port 33. Namely, the measuring block 40 has an opening, a bottom of which is of a near rectangular parallelepiped shape, formed in the horizontal direction with respect to the outer wall surface 41, wherein the opening having the bottom is employed as the measuring space S and an opening part thereof serves as the transfer port 33.

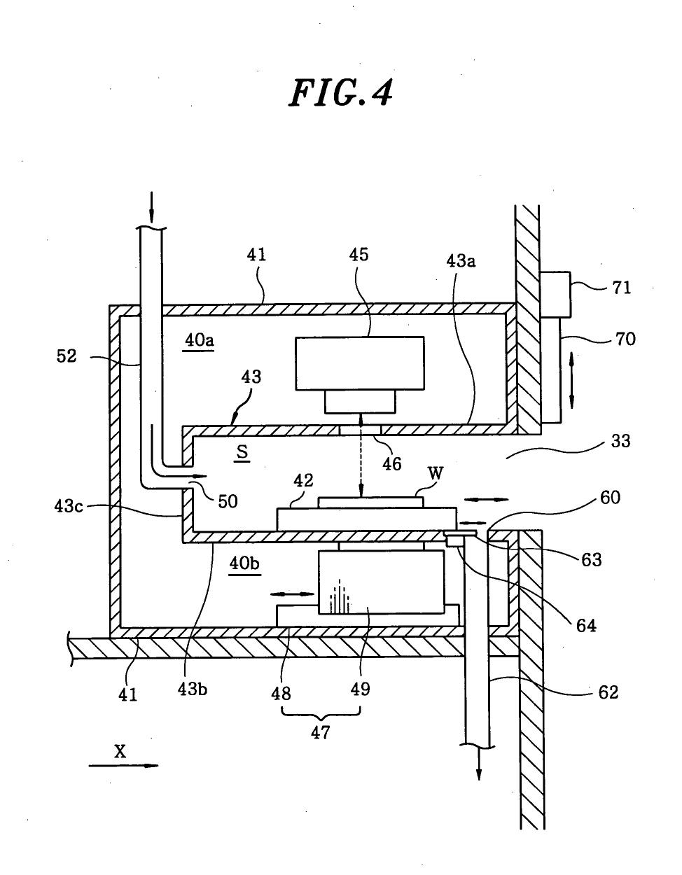

In the measuring space S, there is provided a disk-shaped mounting plate 42 as a mounting unit for mounting thereon, e.g., the wafer W. As illustrated in FIG. 4, the measuring block 40 has therein, e.g., a hollow between the outer wall surface 41 defining an outward appearance thereof and an inner wall surface 43 defining the measuring space S. An optical system 45 as an optical measuring unit having a light irradiating part and a light receiving part is disposed inside an upper hollow portion 40a between the outer wall surface 41 of the measuring block 40 and a ceiling inner wall surface 43a of the measuring space S. By the inner wall surface 43 of the measuring space S, air ventilation between the optical system 45 and the measuring space S is intercepted, so that, e.g., the processing gas supplied from the transfer port 33 does not get into a contact with the optical system 45. The optical system 45 irradiates a light beam, e.g., onto the wafer W on the mounting plate 42 and then receives the reflected light beam therefrom, and measures a reflectivity thereof to obtain a film thickness of the etched layer on the wafer W.

At a position facing the optical system 45 in the ceiling inner wall surface 43a of the measuring space S, there is formed a transmission window 46 as a transparent transmission window. Through the transmission window 46, the optical system 45 can irradiate a light beam to the wafer W on the mounting plate 42 and receive a reflected light beam therefrom.

For example, a lower hollow unit 40b is formed between a bottom inner wall surface 43b of the measuring space S and the outer wall surface 41 of the measuring block 40 disposed therebelow. In the lower hollow unit 40b, there is provided a moving mechanism 47 for moving, e.g., the mounting plate 42 in the direction of the transfer port 33 (X direction). The moving mechanism 47 includes a rail 48 formed, e.g., along the X direction; and a stage 49 for upwardly supporting the mounting plate 42 to be freely moved on the rail 48. The stage 49 can move on the rail 48 by a driving unit, e.g., a built-in motor or the like.

An air supply port 50 is formed at a position facing the transfer port 33 in an inner wall surface 43c of the measuring space S. The air supply port 50 is formed towards the transfer port 33. For example, as described in FIG. 2, to the air supply port 50, there is coupled an air supply duct 52 communicating with an air inlet opening 51 formed on a top surface of the housing 30. The supply duct 52 passes through the measuring block 40, e.g., from the air supply port 50, and communicates with the air inlet opening 51 through the measuring unit 31 at the outer side of the measuring block 40. In the air supply duct 52, there are provided a fan 53 for inhaling an air outside the housing 30; and a filter 54 for removing an impurity such as dusts and the like from the air, which has been supplied through the air supply duct 52. The air introduced from the air inlet opening 51 by the fan 53 turns into a clean gas through the filter 54, and then, supplied from the air supply port 50 into the measuring space S. The air supplied into the measuring space S runs towards the transfer port 33, and flows on the mounting plate 42 to be discharged from the transfer port 33. By such an air supply, the processing gas supplied from the transfer port 33 into the measuring space S is diluted or sent back, and therefore, the measuring space S can be maintained at a clean gas atmosphere.

Further, for example, the number of revolutions of the fan 53 is adjusted by the control unit 65, which adjusts the number of revolutions of the fan 53, to control a flow rate of air supplied into the measuring space S.

Gas exhaust ports 60 are formed at the bottom inner wall surface 43b as a bottom surface of the measuring space S. For example, as illustrated in FIG. 3, the gas exhaust ports 60 are formed at two parts in the vicinity of the transfer port 33 at a downstream side of the mounting plate 42 with respect to the air supply of the air supply port 50. To each gas exhaust port 60, connected is an exhaust duct 62 communicating with a discharge port 61 formed in a side of the transfer chamber 10 of the housing 30, as shown in FIG. 2. The exhaust duct 62 communicates with the discharge port 61, e.g., through the measuring block 40 and the control unit 32. An exhaust shutter 63 sliding, e.g., in the horizontal direction, is provided at the gas exhaust port 60. The exhaust shutter 63 is opened or closed by an exhaust shutter driving unit 64 having a cylinder and the like.

On the housing 30, there is provided a transfer shutter 70 moving in up and down directions to open or close the transfer port 33. The transfer shutter 70 is operated by a transfer driving unit 71 having, e.g., a cylinder and the like.

Operations of the exhaust shutter driving unit 64 and the transfer shutter driving unit 71 are controlled, e.g., by the control unit 65. Thus, the control unit 65 can open or close the exhaust shutter 63 or the transfer shutter 70 with a predetermined timing.

An anti-corrosion processing against the processing gas is performed on an exposed surface to the processing gas in the measuring space S, e.g., on the inner wall surface 43 of the measuring space S and a surface of the mounting plate 42. As for the anti-corrosion processing, employed is a method for coating the exposed surface with a thin film, such as a metal oxide film coating, e.g., Al₂O₃, or a method for coating a fluorine-based resin such as Teflon (registered trademark of Dupont) or the like by a sintering. Further, if the fluorine-based resin is coated, it does not react with acid or base, thereby, imparting a superior corrosion resistance.

In the following, a wafer processing, which is performed in the substrate processing system 1 as configured above, will be explained. During the processing of the wafer W, e.g., a down-flow by a clean gas by the air supply unit U is formed, e.g., in the transfer chamber 10. First, as shown in FIG. 1, if the cassette C accommodating therein an unprocessed wafer W is mounted in the cassette mounting unit 2, the wafer W is first unloaded from the cassette C by the transfer mechanism 20 of the transfer chamber 10 before being transferred to the alignment unit 5. The wafer W positioned in the alignment unit 5 is transferred to the load-lock chamber 11 by the transfer mechanism 20 before being transferred to the etching apparatus 3 by the transfer mechanism 21. The wafer W transferred to the etching apparatus 3 is subject to the etching process by using a predetermined processing gas.

The etched wafer W then is transferred to the load-lock chamber 11 by the transfer mechanism 21 before being transferred to the measuring apparatus 4 by the transfer mechanism 20. In the measuring apparatus 4, a film thickness of the etched layer on the wafer W is measured, and an etching status of the wafer W is determined. The wafer W, which has been examined by the measuring apparatus 4, returns to the cassette C of the cassette mounting unit 2 by the transfer mechanism 20.

Here, an operation of the aforementioned measuring apparatus 4 will be explained, more specifically. During the operation of the substrate processing system 1, a processing gas escaping from the etching apparatus 3 may enter the transfer chamber 10 through the load-lock chamber 11, or by attaching itself to the Wafer W.

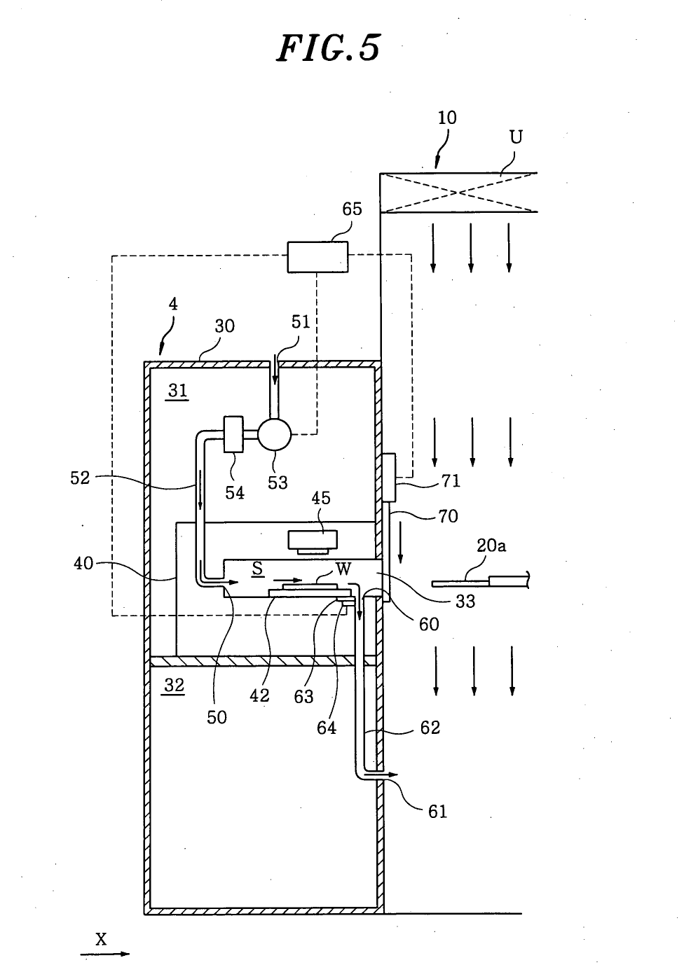

First, if the measurement on the wafer W is not performed in the measuring apparatus 4 and the wafer W is not loaded thereinto, the transfer shutter 70 is closed, e.g., as shown in FIG. 5. Further, the fan 53 is operated to supply a clean air from the air supply port 50 into the measuring space S. Still further, the exhaust shutter 63 is opened to discharge from the gas exhaust port 60 the clean air passing through the measuring space S. As mentioned above, in case when the measurement on the wafer W is not performed in the measuring apparatus 4, an air flow of the clean air, running from one end portion to the other end portion in a closed measuring space S, is formed, and therefore, an inside of the measuring space S is maintained at a clean air atmosphere.

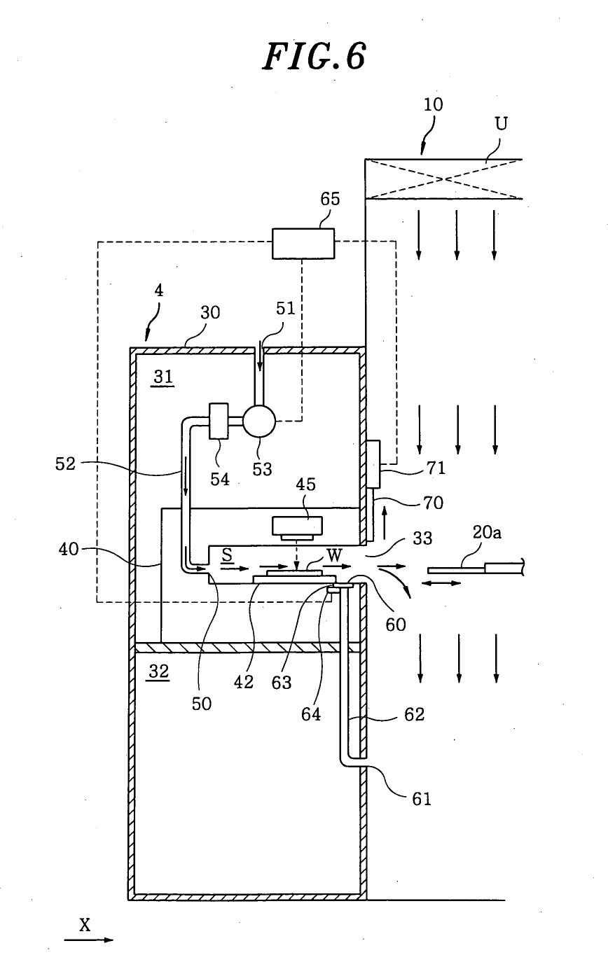

As illustrated in FIG. 6, if the wafer W is loaded into the measuring apparatus 4 by the transfer arm 20a of the transfer mechanism 20, the transfer shutter 70 is opened. While the air supply from the air supply port 50 is maintained, the gas exhaust port 60 is closed by the exhaust shutter 63 thereof. In this way, the air flow of the clean air, introduced from the air supply port 50 and discharged through the transfer port 33, is formed in the measuring space S. By such an air flow, the processing gas introduced from the transfer chamber 10 side into the measuring space S through the transfer port 33 is diluted or sent back.

Further, a flow rate of air to be supplied is set to be smaller than that of the down-flow of the transfer chamber 10 outside the transfer port 33. In this way, the air-flow discharged from the measuring space S and the down-flow may be smoothly joined with each other, and an eddy may be suppressed from being generated around the transfer port 33. Thus, impurities such as dusts and the like may not move upward in the transfer chamber 10.

After the transfer port 33 is opened by the transfer shutter 70, i.e., by moving the mounting plate 42 toward the transfer port 33 towards a positive direction in the X direction, the wafer W is transferred from the transfer arm 20a to the mounting plate 42 to be mounted thereon. After the wafer W is mounted on the mounting plate 42, the mounting plate 42 is moved in the X direction towards the negative direction thereof, and the wafer W is moved to a predetermined measurement position below the optical system 45. Thereafter, the optical system 45 irradiates a light beam to the wafer W and receives the reflected light beam therefrom, so that a film thickness of the etched film, e.g., on the wafer W, is measured. In the meantime, the air flow of the clean air, horizontally running towards the transfer port 33, is formed in the measuring space S, and the processing gas coming thereinto, e.g., accompanied by the wafer W, is sent back to the transfer port 33 side.

Once the measurement by the optical system 45 is completed, the wafer W is delivered again to the transfer arm 20a before being unloaded from the measuring apparatus 4. After the wafer W is unloaded, the transfer shutter 70 is closed and the exhaust shutter 63 of the gas exhaust port 60 is opened again; and the air flow of the clean air, running from the air supply port 50 towards the gas exhaust port 60, is established in the measuring space S, during which the measuring space S remains closed.

In accordance with the aforementioned embodiment, an openable measuring space S is formed on the transfer port 33 inside the measuring apparatus 4, and air ventilation between the optical system 45 and the measuring space S is intercepted by the wall of the measuring space S. Thus, the processing gas used in the etching apparatus 3 does not come into a contact with the optical system 45, and the optical system 45 is prevented from being corroded and contaminated, due to a corrosion inducing/corrosive gas such as an acidic like, contained in the processing gas. Accordingly, the measurement accuracy of the optical system 45 may not deteriorate even after a prolonged use, and the life time thereof can be increased. Further, the possibility of the optical system 45 getting contaminated by the processing gas, which, in turn, may lead to the wafer W in the measuring apparatus 4 being contaminated, as observed in the conventional art.

Since the exposed surface in the measuring space S is subject to the anti-corrosion processing, the measuring space S may not become corroded due to the corrosion inducing/corrosive gas introduced thereinto. Thus, contamination of the wafer W, caused by contaminants from the corrosion in the measuring space S depositing on top thereof, may not occur.

The measuring block 40 is provided in the housing 30 of the measuring apparatus 4, and the measuring space S is formed to accommodate therein only the mounting plate 42 by the corresponding measuring block 40, so that an exposed portion with respect to the transfer chamber 10 through the transfer port 33 is minimally suppressed. For the same reason, an area to be subjected to the anti-corrosion processing is reduced, and therefore, it is possible to reduce the cost for the anti-corrosion processing. Further, since the processing gas does not come into a contact with other parts as well as the optical system 45 in the measuring apparatus 4, it is possible to reduce corrosion or contamination.

Since the optical system 45 is provided in the upper hollow portion 40a of the measuring apparatus 40, it does not come into a contact with an atmosphere outside the measuring block 40 as well as the measuring space S, and hence, corrosion or contamination in the optical system 45 can be further decreased.

Since the transparent window 46 is provided in the ceiling inner wall surface 43a of the measuring space S, it is possible to properly conduct the measurement on the wafer W by using the optical system 45.

Since the air supply port 50 heading for the transfer port 33 side is provided at a position facing the transfer port 33 in the inner wall surface 43a of the measuring space S, the processing gas introduced from the transfer chamber 10 side into the measuring space S can be diluted or sent back. Further, impurities, such as the corrosion inducing/corrosive gas or the like, entering with the wafer W loaded into the measuring space S can be forced to flow toward the transfer chamber 10. In this way, it is possible to suppress contamination of the measuring space S, due to the corrosion inducing/corrosive gas or the like.

The air inlet opening 51 is formed on the top surface of the housing 30, and the fan 53 and the filter 54 are provided in the air supply duct 52 connecting the air inlet opening 51 to the air supply port 50. Thus, the air at the outer side of the housing 30 is cleaned, and then, supplied into the measuring space S. In such a case, since the clean gas can be supplied into the measuring space S by using the air around the housing 30, it is possible to reduce the cost for the clean gas.

Since the gas exhaust port 60 is formed in the vicinity of the transfer port 33 of the measuring space S, the air supplied from the air supply port 50 flows on the mounting plate 42 before being discharged. Accordingly, if the measurement on the wafer W is not conducted, the transfer shutter 70 is closed to clean the measuring space S. Further, since the gas exhaust port 60 is formed at the bottom inner wall surface 43b of the measuring space S, it is possible to effectively discharge the corrosion inducing/corrosive gas such as HCl, HBr or the like, which is heavier than the air, and thus, being likely to be collected on the bottom inner wall surface 43b. Still further, since the discharge port 61 communicating with the gas exhaust port 60 is formed in the housing 30 of the transfer chamber 10 side below the transfer port 33, the gas passing through the measuring space S can be joined with the down-flow of the transfer chamber 10, to thereby, be discharged to the outside of the substrate processing system 1 with the corresponding down-flow. For the same reason, the exhaust from the measuring space S can be properly discharged by using the down-flow.

In the aforementioned embodiment, if the measurement on the wafer W is not conducted, the transfer shutter 70 remains closed by the control unit 65, and the air supply from the air supply port 50 and the exhaust from the exhaust port 70 are continuously carried out. However, at this time, it can be configured such that the air supply and the exhaust are performed for a predetermined time while the transfer shutter 70 remains closed, e.g., by the control unit 65; and, if the measuring space S is cleaned, they are stopped. In such a case, also, it is possible to maintain the measuring space S at a clean state.

Further, in the aforementioned embodiment, when the measurement on the wafer W is conducted, the transfer shutter 70 is opened by the control unit 65, the air supply from the air supply port 50 is performed and the exhaust from the exhaust port 60 is stopped. However, at this time, it can be configured such that the transfer shutter 70 remains closed by the control unit 65, and both of the air supply and exhaust can be carried out. In such a case, if the wafer W is loaded into the measuring space S, the measuring space S is closed, and the air supply of the clean gas and the exhaust thereof are carried out from the closed measuring space S. Therefore, during the measurement on the wafer W, the introduction of the processing gas from the transfer chamber 10 into the measuring space S is intercepted by the transfer shutter 70, so that the measuring space S is kept clean by the air supply from the air supply port 50 and the exhaust from the gas exhaust port 60.

In the optical system 45 described in the aforementioned embodiment, a reference member for correction is required. The reference member may have a predetermined common quality and surface shape; and the measuring apparatus 45 actually performs a measurement on the reference member to obtain intrinsic reference data of each measuring apparatus, which is required for the measurement on the wafer W.

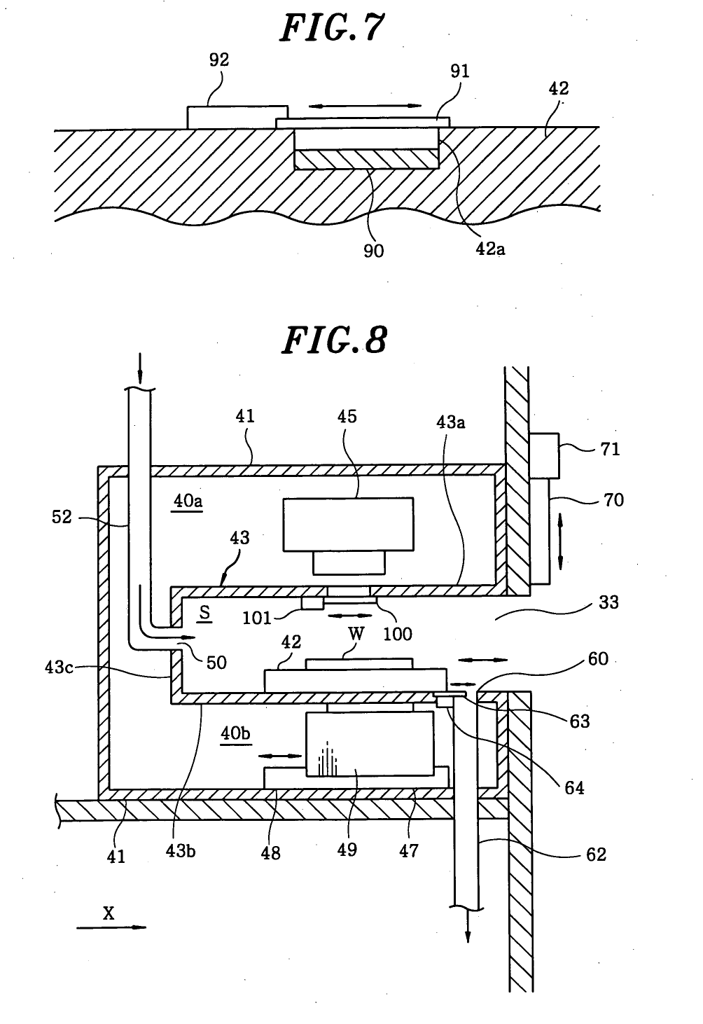

For example, as shown in FIG. 7, a recessed portion 42a is formed at a predetermined position on a surface of the mounting plate 42, wherein a reference chip 90 as the reference member is buried. On a surface of the reference chip 90, there is formed, e.g., a flat silicon (bare silicon).

On the reference chip 90, there is provided a protection shutter 91 moving in the horizontal direction to open or close the recess portion 42a. The protection shutter 91 can move by a protection shutter driving unit 92 having, e.g., a cylinder and the like. Further, the protection shutter 91 is opened to allow the reference chip 90 to be opened in the measuring space S, if the reference chip 90 is employed. Still further, the protection shutter 91 is closed to cover the reference chip 90, if the reference chip 90 is not used. In this way, the exposure time of the reference chip 90 with respect to the atmosphere in the measuring space S is shortened, and it is possible to suppress the corrosion or contamination of the reference chip 90, due to the processing gas. As a result, the correction on the optical system 45 is properly conducted.

Further, the reference chip 90 may be provided at a part other than the mounting plate 42, e.g., on a bottom surface of the measuring space S. In such a case also, since the protection shutter 91 is provided, it is possible to suppress the corrosion or contamination of the reference chip 90.

For example, as illustrated in FIG. 8, in the transmission window 46 described in the aforementioned embodiment, there may be provided a transparent window protection shutter 100 for protecting the transmission window 46 from the processing gas in the measuring space S. A plate-shaped transparent window protection shutter 100 is provided, e.g., at a bottom surface side of the transmission window 46, to slide freely in the horizontal direction. The protection shutter 100 can slide by a shutter driving unit 101, e.g., cylinder or the like. Further, if the measurement is conducted by the optical system 45, the transparent window protection shutter 100 is opened by the shutter driving unit 101 such that the transmission window 46 is opened in the measuring space S. Once the measurement by the optical system 45 is completed, the transparent window protection shutter 100 is closed to cover the transmission window 46. In this case, since the transmission window 46 is protected from the processing gas introduced into the measuring chamber S, the measurement accuracy in the optical system 45 is maintained.

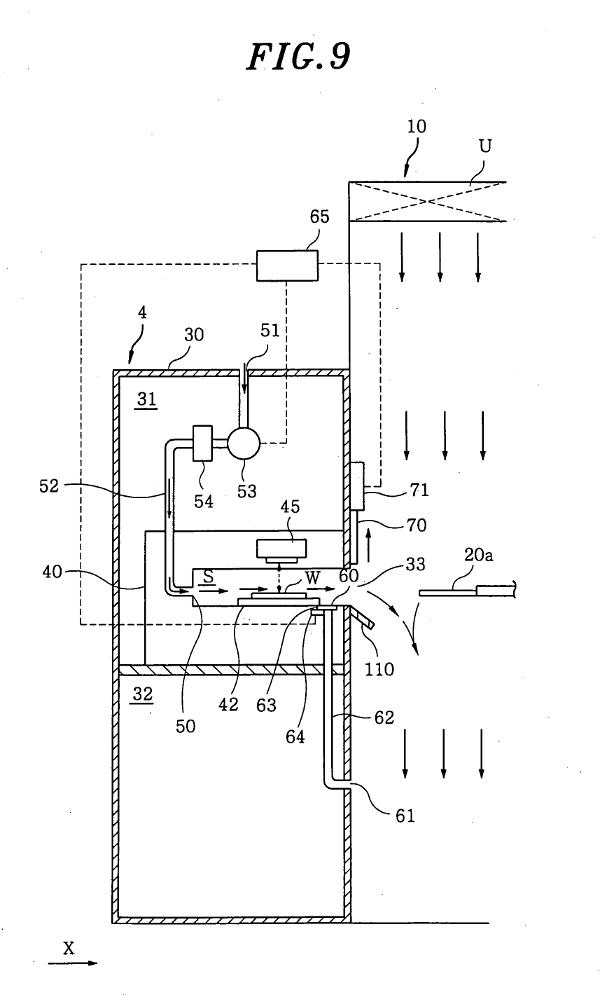

As shown in FIG. 9, at the transfer port 33 of the measuring space S described in the aforementioned embodiment, there may be provided a flow rectifying plate 110 for rectifying an air flow at a point where the flow of the air discharged from the transfer port 33 through the measuring space S is joined with the down-flow in the transfer chamber 10 outside the transfer port 33. For example, the flow rectifying plate 110 is formed toward the dip angle direction from an end portion of the transfer port 33 side at the bottom surface of the measuring space S. By the flow rectifying plate 110, the flow of the air discharged from the transfer port 33 can be smoothly joined with the down-flow, and the air flow may not be scattered at a junction thereof. As a result, it does not occur that the down-flow in the transfer chamber 10 does not scatter and particles fly upward; and contamination of the transfer wafer W can be suppressed.

Heretofore, one example of preferred embodiments of the present invention has been explained, but the present invention is not limited thereto and various modifications can be made. For example, while the measuring apparatus 4 described in the present embodiment involves measuring a film thickness of the etched layer, other measurement on the wafer W can be conducted, such as a pattern structure formed on the wafer surface, e.g., a pattern shape thereon after the etching. A plurality of measuring apparatues may be mounted on the substrate processing system 1. Further, a mounting position of the measuring apparatus may be selected arbitrarily. In the substrate processing system 1 described in the present embodiment, while the etching apparatus 4 is mounted, another gas processing apparatus using a processing gas may be mounted, such as a film forming apparatus, ashing apparatus, substrate surface polishing apparatus and developing apparatus using acid-base chemical, or the like. Further, configurations of the transfer apparatus 6, the cassette mounting unit 2 and the like in the substrate processing system are not limited to the present embodiment. Still further, the present invention is applicable for other substrate processing system 1 such as an FPD (flat panel display) substrate, a photo-mask glass substrate or the like, as well as a semiconductor wafer.

### EFFECT OF THE PRESENT INVENTION

In accordance with the present invention, the measurement accuracy in a measuring apparatus is maintained, and lifetime thereof is prolonged. Further, it is possible to prevent the contamination of the substrate to be subjected to a measurement in the measuring apparatus.

While the invention has been shown and described with respect to the preferred embodiments, it will be understood by those skilled in the art that various changes and modifications may be made without departing from the scope of the invention as defined in the following claims.

What is claimed is:

1. A substrate processing system, comprising:
a gas processing apparatus for processing a substrate by using a processing gas;
a measuring apparatus for performing a measurement on the substrate processed in the gas processing apparatus; and
a transfer apparatus for transferring the substrate processed in the gas processing apparatus to the measuring apparatus, all the apparatus being integrated in the system as a single unit,
wherein the measuring apparatus includes a mounting unit for mounting the substrate; an optical measuring unit for performing a measurement on the substrate mounted on the mounting unit by irradiating a light beam thereto; and a measuring space having therein the mounting unit, in which the measurement is conducted on the substrate mounted on the mounting unit,
wherein, in the measuring space, there is opened a substrate transfer port for transferring the substrate to the mounting unit by the transfer apparatus, and
wherein the measuring space and a space where the optical measuring unit is accommodated are airtightly isolated from each other by a wall defining the corresponding measuring space.

2. The substrate processing system of claim 1, wherein an anti-corrosion processing against the processing gas is performed on an exposed surface in the measuring space.

3. The substrate processing system of claim 1, wherein the measuring space is formed to accommodate therein only the mounting unit.

4. The substrate processing system of claim 1, wherein the measuring space is of a rectangular parallelepiped shape, one side of which corresponds to the substrate transfer port.

5. The substrate processing system of claim 1, wherein the measuring apparatus further includes a housing; and a measuring block, provided in the housing, for forming the measuring space, and
wherein the measuring block has an outward appearance of a rectangular parallelepiped shape; and the measuring space is formed in a sidewall surface of the measuring block in a recessed shape.

6. The substrate processing system of claim 5, wherein the optical measuring unit is provided in a hollow portion of the measuring block between an inner wall surface defining the measuring space and an outer wall surface defining the outward appearance of the measuring block.

7. The substrate processing system of claim 1, wherein, in the wall of the measuring space isolating the optical measuring unit, there is formed a transmission window through which the light beam irradiated from the optical measuring unit is transmitted.

8. The substrate processing system of claim 7, wherein, the transmission window is provided with a transmission window protection shutter for protecting the transmission window from the processing gas.

9. The substrate processing system of claim 1, wherein, at a position facing the substrate transfer port on a sidewall of the measuring space, there is formed an air supply port for supplying a clean gas toward the substrate transfer port.

10. The substrate processing system of claim 9, wherein, in the measuring space, there is formed a gas exhaust port for exhausting the clean gas, which is supplied from the air supply port, in the vicinity of the substrate transfer port at a downstream side below the mounting unit.

11. The substrate processing system of claim 10, wherein, the gas exhaust port is formed at a bottom surface of the measuring space.

12. The substrate processing system of claim 10, further comprising:
a shutter for opening or closing the substrate transfer port; and
a control unit for performing an air supply from the air supply port and stopping an exhaust from the exhaust port while the shutter is opened; and performing the air supply from the air supply port and the exhaust from the gas exhaust port while the shutter is closed.

13. The substrate processing system of claim 9, further comprising:
an air inlet port for introducing an air of an outer side of the measuring apparatus;
an air supply duct in communication with the air inlet port and the air supply port; and
a filter for removing impurities from an air passing through the air supply duct.

14. The substrate processing system of claim 9, wherein a downflow is formed at an outside of the substrate transfer port, and
wherein a flow rate of air supplied from the air supply port is set to be smaller than that of the downflow.

15. The substrate processing system of claim 9, wherein a downflow is formed at an outer side of the substrate transfer port, and
wherein, at the substrate transfer port, there is provided a flow rectifying plate for rectifying an air flow at a point where a flow of the clean gas in the measuring space is joined with the downflow.

16. The substrate processing system of claim 1, wherein, in the measuring space, there is provided a reference member, to which the light beam from the optical measuring unit is irradiated, for correcting the measurement performed by the optical measuring unit, and
wherein the reference member is provided with a protection shutter for protecting the reference member from the processing gas.
